(19) United States
(12) Patent Application Publication
(10) Pub. No.: US 2025/0097081 A1
(43) Pub. Date: Mar. 20, 2025

(54) COMPLEX-ZERO EQUALIZER CIRCUIT

(71) Applicant: Intel Corporation, Santa Clara, CA (US)

(72) Inventors: Sashank Krishnamurthy, Hillsboro, OR (US); Mozhgan Mansuri, Portland, OR (US)

(21) Appl. No.: 18/467,659

(22) Filed: Sep. 14, 2023

(51) Int. Cl. H04L 25/03; H01S 5/42

(52) U.S. Cl. CPC H04L 25/03878; H01S 5/423; H04L 25/03019

(57) ABSTRACT

Embodiments herein relate to an equalizer in a communication system. In an example implementation, the communication system is an optical system including a Vertical-Cavity Surface-Emitting Laser (VCSEL). A transfer function of the equalizer has two complex-zeroes to compensate for a group delay variation due to an underdamped complex-pole pair of the VCSEL optical response. The equalizer may include a first transistor having a control gate coupled to an input path, a drain coupled to an output path, and a source, and first, second and third paths coupled between the source and ground. The first path includes, in series, a resistor, a node and a capacitor, the second path includes a second transistor having a control gate coupled to the node, and the third path includes a capacitor. A tuning process can be used to achieve a desired frequency and quality factor.

### FIELD

The present application generally relates to an equalizer in a communication system.

### BACKGROUND

The ever-growing demand for high-performance and energy efficient communications such as in data centers and computing applications has driven the development of communication links, including electrical and optical links. However, various challenges are presented, including addressing variations in group delay which result in ringing in the pulse response and a degradation in the eye-width.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1A depicts an example group delay of a broadband system with a complex-pole pair having a peak in the group delay response, cascaded with a following complex-zero equalizer having a dip in the group delay response, to produce a flat group delay profile, in accordance with various embodiments.

FIG. 1B depicts an example group delay of a broadband system with a complex-pole pair having a peak in the group delay response, cascaded with a preceding complex-zero equalizer, to produce a flat group delay profile, in accordance with various embodiments.

FIG. 2 depicts an example optical transmitter 200 including a driver 201 containing a complex-zero equalizer, in accordance with various embodiments.

FIG. 3 depicts an example optical receiver 300 including a trans-impedance amplifier 350 and a following complex-zero equalizer circuit 340, in accordance with various embodiments.

FIG. 4 depicts an example real-zero equalizer 400, in accordance with various embodiments.

FIG. 5 depicts an example complex-zero equalizer 500, in accordance with various embodiments.

FIG. 6A depicts an example equalizer 600 which can be configured as a complex-zero equalizer or a real-zero equalizer based on a switch SW, in accordance with various embodiments.

FIG. 6B depicts an equalizer circuit 605 which is equivalent to the equalizer 600 of FIG. 6A when the equalizer 600 is configured in a real-zero equalizer mode, in accordance with various embodiments.

FIG. 7 depicts an example equalizer 700 which is a Complementary Metal-Oxide Semiconductor (CMOS) implementation of an active complex-zero continuous time linear equalizer (CTLE), in accordance with various embodiments.

FIG. 8A depicts an example second-order under-damped transfer function for a Vertical Cavity Surface Emitting Laser (VCSEL), in accordance with various embodiments.

FIG. 8B depicts an example transfer function in terms of Vout/Vin of the complex-zero pair, in accordance with various embodiments.

FIG. 8C depicts an example equation for frequency of the zero-pair of the complex-zero pair, in accordance with various embodiments.

FIG. 8D depicts an example equation for a quality (Q)-factor of the complex-zero pair, in accordance with various embodiments.

FIG. 9 depicts a flowchart of an example process for tuning a complex-zero equalizer, in accordance with various embodiments.

FIG. 10A depicts example plots of group delay versus frequency for the optical transmitter of FIG. 2 with and without the complex-zero equalizer 500 of FIG. 5, in accordance with various embodiments.

FIG. 10B depicts an example eye diagram of the output of the optical transmitter of FIG. 2 without the complex-zero equalizer 500 of FIG. 5, in accordance with various embodiments.

FIG. 10C depicts an example eye diagram of the output of the optical transmitter of FIG. 2 with the complex-zero equalizer 500 of FIG. 5, in accordance with various embodiments.

FIG. 11 illustrates an example of components that may be present in a computing system 1150 for implementing the techniques (e.g., operations, processes, methods, and methodologies) described herein.

### DETAILED DESCRIPTION

As mentioned at the outset, various challenges are presented in operating high-performance and energy efficient communication systems. Such communication system may transmit signals in multiple channels or lanes with a per-lane data rate of >64 Gb/see, for example. One approach is to replace electrical links with optical links such as Vertical Cavity Surface Emitting Laser (VCSEL)-based optical links. Optical links are seen as a replacement candidate for electrical links for rack-to-rack connectivity in data centers with a range of tens to hundreds of meters, for example.

However, the linearized optical response of the VCSEL around the bias point is a second order under-damped transfer function. This results in a significant variation in group delay within the bandwidth of interest and consequently, ringing in the pulse response, and a degradation in the eye-width. To this end, it is desirable to build a VCSEL driver which can compensate for this group delay variation. Depending on the VCSEL design parameters and bias point, the natural frequency and damping factor of the optical transfer function vary. For the VCSEL driver to work with different VCSELs and at different bias points, it is desirable for the group-delay compensation to be tunable.

One possible solution is based on a fractional UI (unit interval) feedforward equalizer with asymmetric equalization for rising and falling pulses. However, this approach works well only at lower data rates, e.g., <20 Gb/sec. due to the difficulty in generating small fractional UI delays. Moreover, power consumption tends to be high.

Another possible solution involves attempting to compensate exactly for the frequency-dependent group-delay response. For instance, a multi-stage solution can be provided in Bipolar Complementary Metal-Oxide Semiconductor (BiCMOS) with an emitter-peaking circuit, a positive feedback circuit and a limiting amplifier, with appropriate tuning of each stage. Bipolar CMOS (BiCMOS) is a semiconductor technology that integrates two semiconductor technologies, those of the bipolar junction transistor and the CMOS (complementary metal-oxide-semiconductor) logic gate, into a single integrated circuit. Another example includes two parallel paths which are appropriately summed to synthesize a complex-zero pair to cancel the complex-pole pair. However, multi-stage and multi-path solutions consume high power, need extensive tuning, and potentially have a bandwidth limitation while combining the multiple paths.

The solutions described herein address the above and other issues. In one aspect, a low-power highly tunable complex-zero equalizer is provided for use in electrical or optical communication systems. In an example implementation, the equalizer is for use in a Vertical-Cavity Surface-Emitting Laser (VCSEL) driver to compensate for the group delay variation arising out of the underdamped complex-pole pair of the VCSEL optical response. The complex-zero equalizer may also be used in other circuits with high-Q complex-pole pairs, such as in a high-gain multi-stage shunt-feedback trans-impedance amplifier (TIA).

The solutions compensate for the group delay variation and pulse-response ringing of the VCSEL based on constructing an active complex-zero equalizer to cancel the complex-pole pair in the VCSEL response. This can be implemented, in one approach, by constructing an appropriate active shunt degeneration impedance to synthesize the complex-zero pair. The frequency and the damping factor of the complex-zeroes may be tuned to compensate for different VCSELs and bias points. In an example implementation, the equalizer is capable of equalizing complex-pole pairs with a natural frequency range of at least 18.2 GHz-25.2 GHz and a wide range of damping factors greater than 0.34.

A number of advantages can be achieved. First, the use of an active complex-zero equalizer can support VCSEL-based links at more than 64 Gb/see with non-return-to-zero (NRZ) binary code, which is more than 50% faster than the native data rate of the VCSELs.

A second advantage is that the equalizer can improve power efficiency compared to other techniques by employing a tuning process which involves changing one or more resistance, capacitances and/or transconductances in the equalizer.

A third advantage is that the complex-zero equalizer may also be used in other systems such as a multi-stage shunt-feedback trans-impedance amplifier.

These and other features will be further apparent in view of the following discussion.

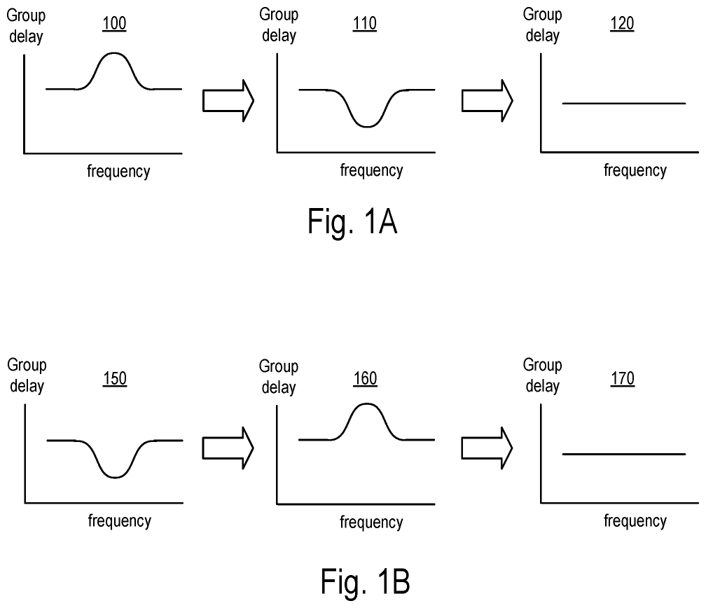

FIG. 1A depicts an example group delay of a broadband system with a complex-pole pair having a peak in the group delay response, cascaded with a following complex-zero equalizer having a dip in the group delay response, to produce a flat group delay profile, in accordance with various embodiments. The plots of FIGS. 1A and 1B depict group delay versus frequency. Plot 100 depicts a group delay of a system with a complex-pole pair, where peaking occurs in the group delay. Plot 110 depicts a group delay of a following complex-zero equalizer to compensate for the group delay peaking of plot 100. Plot 120 depicts a flat group delay of the cascaded response of the system and the equalizer.

FIG. 1B depicts an example group delay of a broadband system with a complex-pole pair having a peak in the group delay response, cascaded with a preceding complex-zero equalizer, to produce a flat group delay profile, in accordance with various embodiments. Plot 160 depicts a group delay of a system with a complex-pole pair, where peaking occurs in the group delay. Plot 150 depicts a group delay of a preceding complex-zero equalizer to compensate for the group delay peaking of plot 100. Plot 170 depicts a flat group delay of the cascaded response of the system and the equalizer.

Generally, the figures illustrate of a general broadband system with complex-pole pair having a peak in the group delay response versus frequency. When cascaded with a complex-zero equalizer (placed before or after the system), the cascaded response has a flat group delay profile versus frequency within the operating frequency or system bandwidth.

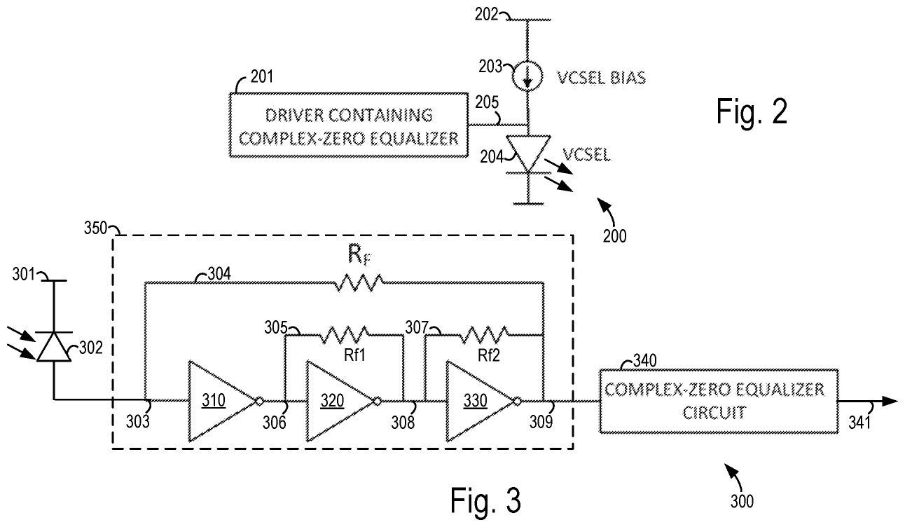

FIG. 2 depicts an example optical transmitter 200 including a driver 201 containing a complex-zero equalizer, in accordance with various embodiments. The transmitter includes a power supply node 202 which powers a current source 203 for a VCSEL 204. The VCSEL emits light which is used to carry data via an optical path such as optical fiber. In this example, a complex-zero continuous time linear equalizer in a driver 201 is used to compensate for the complex-pole pair of the VCSEL. The equalizer provides an output signal on an output path 205 to control the light emission of the photo diode.

FIG. 3 depicts an example optical receiver 300 including a trans-impedance amplifier (TIA) 350 and a following complex-zero equalizer circuit 340, in accordance with various embodiments. The complex-zero equalizer circuit follows the TIA 350 in this example, but alternatively could precede it. In either case, the complex-zero equalizer circuit is in cascade with the TIA and the resulting, cascaded response will have the complex-zero response compensating for the complex-pole pair from the TIA. Here, the complex-zero continuous time linear equalizer compensates for the complex-pole pair of the frequency response of the TIA which has a small feedback resistance Rf. The TIA is used to translate the current output of the photodiode to a corresponding voltage signal on the output path 309. The circuit 340 in turn provides an output on an output path 341 for further processing/decoding based on the signal on the output path 309 of the TIA, which is an input path of the equalizer.

The receiver includes a photodiode 302 or other photo sensor which is biased by a power supply node 301, e.g., at a voltage Vdd. The photodiode converts a received optical signal into a current which is amplified by the TIA. The TIA includes a first inverter 310 followed by a second inverter 320 which in turn is followed by a third inverter 330. A feedback path 304 extends from the output path 309 of the third inverter to the input path 303 of the first inverter and includes the feedback resistor Rf. A feedback path 305 also extends from the output 306 of the first inverter to its input path 303 and includes the feedback resistor Rf1. A feedback path 307 also extends from the output path 309 of the third inverter to its input 308 and includes the feedback resistor Rf2.

Note that while a multi-stage TIA is depicted, a single-stage TIA is an option as well. While the complex-zero equalizer was used to compensate for a multi-stage TIA response as an example, it may also be used to compensate for any broadband trans-impedance amplifier or generally any broadband amplifier with a complex-pole pair in its response.

Also, this example assumes there is one communication/data path. In a system which uses two communication paths, such as in-phase (I) and quadrature phase (Q) path, a separate equalizer is provided for each path.

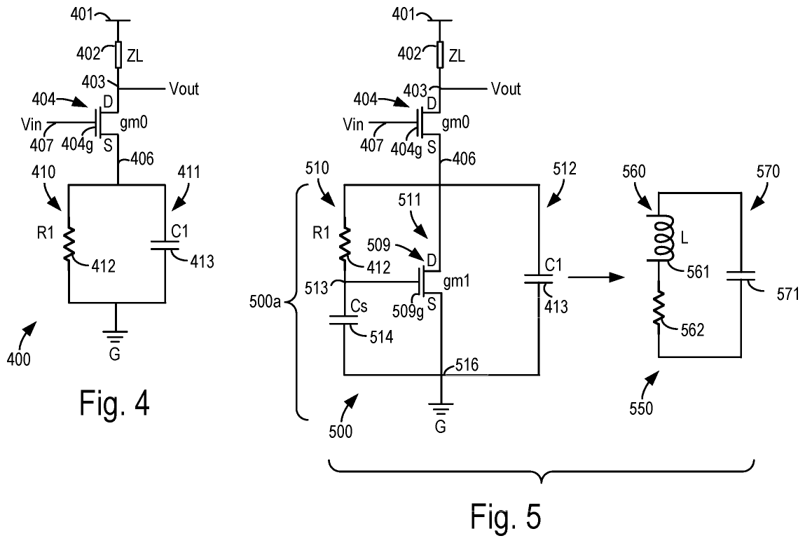

FIG. 4 depicts an example real-zero equalizer 400, in accordance with various embodiments. The equalizer includes a power supply node 401, an impedance component 402 with an impedance ZL, an output path 403 with an output voltage Vout, and a first transistor 404 having a transconductance gm0 and a control gate 404g which receives an input voltage Vin at an input path 407. The transconductance (gm) of a MOSFET refers to a ratio of a change in the drain current to a change in the gate-to-source voltage, Vgs.

Vin can represent a data-carrying signal which has a time-varying amplitude. This data-carrying signal is an input to the equalizer 400. The transistor is an n-type metal-oxide-semiconductor field-effect transistor (nMOSFET) in one example. A drain (D) of the transistor is coupled to the output path 403 and a source (S) of the transistor is coupled to a path 406 which in turn is coupled to one end of parallel paths 410 and 411. The first path 410 includes a resistor 412 having a resistance R1 and the second path 411 includes a capacitor 413 having a capacitance C1. A terminal end of each of the parallel paths 410 and 411 is coupled to ground (G).

FIG. 5 depicts an example complex-zero equalizer 500, in accordance with various embodiments. Generally, the path 406 and the source of the transistor 404 are coupled to a circuit 500a of the equalizer which adjusts a bias of the source, in an example implementation. For example, the circuit 500a can include paths 510, 511 and 512. The first path 510 includes, in a serial sequence, the resistor 412, a node 513 and a first capacitor 514 having a first capacitance Cs. The second path 511 includes a second transistor 509 having a transconductance gm1. The transistor is an nMOSFET in this example having a control gate 509g coupled to the node 513. The third path 512 includes a second capacitor 413 having a second capacitance C1. A terminal end of each of the paths 510-512 at node 516 is coupled to ground. The equalizer is an active complex-zero continuous time linear equalizer (CTLE).

The complex-zero equalizer 500 can be represented by an equivalent circuit 550 which includes parallel paths 560 and 570, where the path 560 includes an inductor 561 having an inductance L in series with a resistor 562 and the path 570 includes a capacitor 571.

In an example implementation, the equalizer 500 comprises: an input path 407 to receive an input voltage; a first transistor 404 having a control gate 404g coupled to the input path, a drain D coupled to an output path 403, and a source S; and first, second and third paths 510, 511 and 512, respectively, coupled between the source and ground; wherein: the first path comprises, in a serial sequence, a resistor 412, a node 513 and a capacitor 514; the second path comprises a second transistor 509 having a control gate 509g coupled to the node 513; and the third path comprises a capacitor 413.

The specific arrangement of transistor, resistor and capacitor is equivalently modeled by an inductor in series with a resistor and the series combination in shunt with a capacitor. With appropriate values set by the equations, a complex-zero equalizer can be realized.

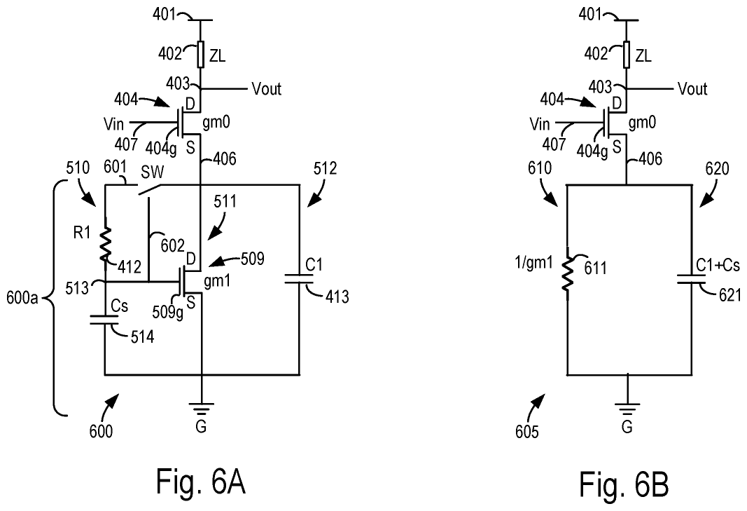

FIG. 6A depicts an example equalizer 600 which can be configured as a complex-zero equalizer or a real-zero equalizer based on a switch SW, in accordance with various embodiments. The path 406 at the source of the transistor 404 is coupled to a circuit 600a of the equalizer 600 which adjusts a bias of the source, in an example implementation. The equalizer includes a switch (SW) to couple the path 406 to the resistor 412 via a path 601 or to a bypass path 602, which bypasses the resistor. Both paths are coupled to the node 513. The bypass path can be coupled to the switch at one end and is coupled to the node 513/control gate 509g at the other end. By short circuiting the resistor 412 with the bypass path, from the path 406 to the node 513, the complex-zero equalizer is turned into a real-zero equalizer.

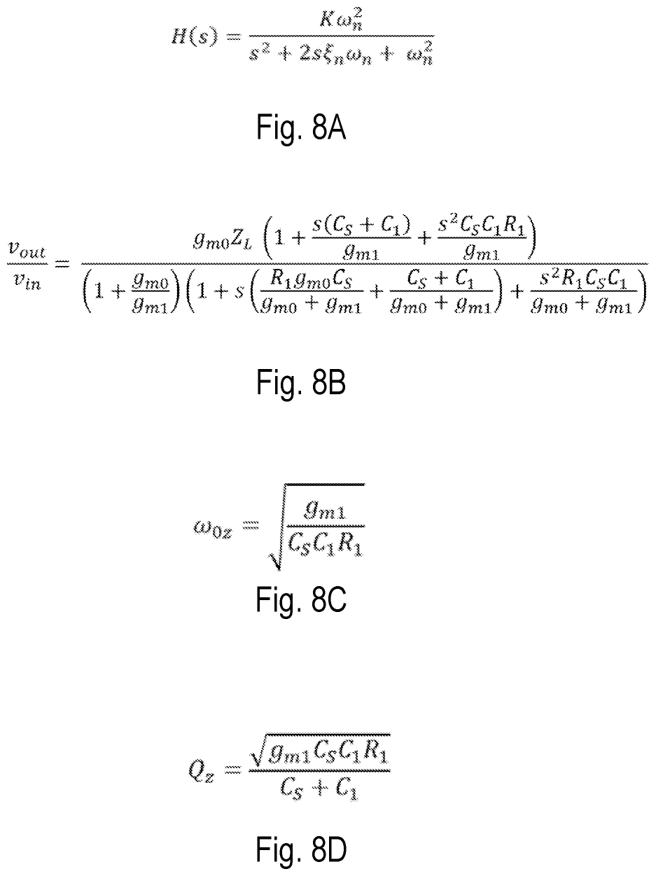

In another option, the resistor 412 is adjustable and may be tuned to a very small value. The switch and bypass path may be omitted in this case. (C1+CS) should be set to place the real-zero at an appropriate frequency as the application demands. The exact value at which the frequency of the real-zero would lie would then be equal to gm1/(C1+CS). A ratio of the capacitors can be set based on the equation of FIGS. 8B-8D. Specifically, the complex-zero pair in the numerator of the equation should cancel the known complex-pole pair of the system in question (e.g., the TIA or the VCSEL). Since the natural frequency and the quality factor of the pole-pair is known, CS, C1, R1 and gm1 can be chosen such that the solution to the complex-zero pair thus obtained matches what is needed.

FIG. 6B depicts an equalizer circuit 605 which is equivalent to the equalizer 600 of FIG. 6A when the equalizer 600 is configured in a real-zero equalizer mode, in accordance with various embodiments. In the equalizer circuit 605, parallel paths 610 and 620 are coupled to the path 406. The first path 610 includes a resistor 611 having a resistance of 1/gm1, and the second path 620 include a capacitor 621 having a capacitance of C1+Cs. A terminal end of each of the parallel paths 610 and 620 is coupled to ground.

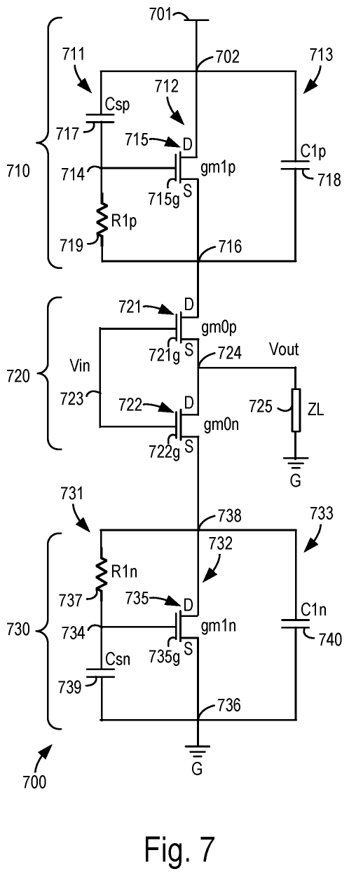

FIG. 7 depicts an example equalizer 700 which is a CMOS implementation of an active complex-zero continuous time linear equalizer (CTLE), in accordance with various embodiments. The CMOS implementation includes the use of both nMOS and pMOS transistors. A CMOS equivalent implementation of FIG. 5 is provided in FIG. 7.

The equalizer 700 includes three subset circuits 710, 720 and 730. The first circuit 710 includes a power supply node 701 coupled to a node 702 which in turn is coupled to paths 711, 712 and 713. The first path 711 includes, in a serial sequence, a capacitor 717 having a capacitance Csp, a node 714 and a resistor 719 having a resistance Rip. The second path 712 includes a third transistor 715 having a transconductance gm1p. The transistor is an nMOSFET in this example having a control gate 715g coupled to the node 714. The third path 713 includes a capacitor 718 having a capacitance C1p. A drain of the third transistor 715 is coupled to the node 702 and a source of the transistor is coupled to the node 716. An end of each of the paths 711-713 is coupled to the node 716, which is an input to the intermediate circuit 720.

The intermediate circuit 720 includes first and second transistors 721 and 722, respectively, coupled to one another in series and having their control gates 721g and 722g, respectively, coupled to one another via a path 723. The path 723 is an input path which receives Vin. The transistors are nMOSFETs in this example. The first transistor 721 has a drain coupled to the node 716 and a source coupled to a node 724. The second transistor 722 has a drain coupled to the node 724 and a source coupled to a node 738. The transistors 721 and 722 have transconductances of gm0p and gm0n, respectively. The node 724 is an output path which carries Vout to an impedance component 725 with an impedance ZL. The impedance component is coupled at its terminal end to ground. The node 738 is an input to the second circuit 730.

The second circuit 730 includes paths 731, 732 and 733 coupled to the node 738. The first path 731 includes, in a serial sequence, a resistor 737 having a resistance Rln, a node 734 and a capacitor 739 having a capacitance Csn. The second path 732 includes a fourth transistor 735 having a transconductance gm1n. A control gate 735g of the fourth transistor 735 is coupled to the node 734. The third path 733 includes a capacitor 740 having a capacitance C1n. A terminal end of each of the paths 731-733 is coupled to ground via a node 736.

FIG. 8A depicts an example second-order under-damped transfer function for a VCSEL, in accordance with various embodiments. The transfer function, H(s)=Vout/Vin, provides the linearized optical response of the VCSEL. K is a gain constant, ω_sub_n is the natural frequency of the zero-pair, and ξ_sub_n is the natural damping factor. The numerator of H(s) is second order, so there are two complex-zeroes. The denominator of H(s) is also second order, so there are two complex-poles. In the transfer function H(s) of a system, the zeroes are the values of s at which H(s)=0 and the poles are the values of s at which H(s)=∞.

In a typical VCSEL, the damping factor ξ_sub_n<1. A continuous time linear equalizer such as in FIG. 4 attempts to equalize for a single-pole channel by introducing a real-zero whose frequency is determined by the shunt RC degeneration. This circuit also introduces a real pole at a much higher frequency. The single-zero equalizer, while useful for channels with a single-pole roll-off, is unable to sufficiently equalize for the VCSEL response, which has a high Q complex-pole pair.

In contrast, the degeneration impedance implemented in the complex-zero equalizer in FIG. 5 includes an active implementation of a series LR impedance in shunt with a capacitor. This introduces a complex-zero pair which compensates for the complex-pole pair of the VCSEL and introduces a pole pair at a much higher frequency. The overall transfer function of the equalizer 500 in terms of Vout/Vin is given by FIG. 8B.

FIG. 8B depicts an example transfer function in terms of Vout/Vin of the complex-zero pair, in accordance with various embodiments. The transfer function includes the transconductances gm0 and gm1, the resistance R1 and the capacitances Cs and C1.

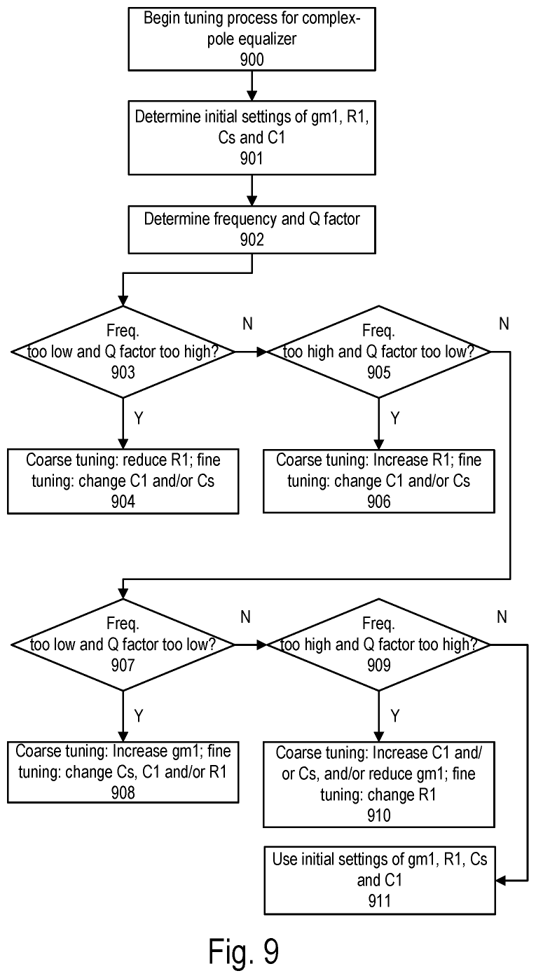

This response, when cascaded with the VCSEL's transfer function, may be used to cancel the complex-pole pair of the VCSEL's response and compensate for the group delay variation and ringing in the pulse response. Moreover, the frequency and quality factor of the zero pair may be tuned by tuning the capacitors Cs and C1 and the resistor R1. See also FIG. 9. Additionally, the transconductance of the degeneration transistor gm1 may also be tuned with some programmability in the sizing of the transistor or the bias voltage of the input transconductance. The load impedance ZL may be a resistor or an active load with or without inductive peaking depending on the native bandwidth of the output node Vout.

With this tuning, the active complex-zero equalizer can compensate for VCSELs in general (including as an example those with damping factors >0.34, a commercially used value, and a natural frequency range of 18.2 GHz-25.2 GHz), which covers different commercial VCSELs at different bias conditions. To achieve a similar tuning range using passive inductors instead of active inductors (e.g., in the circuit of FIG. 5), an inductor of a few hundred pH (pico Henry) with a challenging tuning range of up to 60% is required. The solution using active inductors not only simplifies the tuning but also results in significant area savings due to the absence of passive inductors.

FIG. 8C depicts an example equation for frequency of the zero-pair, ω_sub_n, of the complex-zero pair, in accordance with various embodiments. The frequency of the zero-pair is proportional to the square root of gm1 and inversely proportional to the square root of Cs, C1 and R1.

FIG. 8D depicts an example equation for a quality (Q)-factor of the complex-zero pair, in accordance with various embodiments. The quality factor is proportional to the square root of the product of gm1, Cs, C1 and R1 and inversely proportional to the sum of Cs and C1.

FIG. 9 depicts a flowchart of an example process for tuning a complex-zero equalizer, in accordance with various embodiments. The tuning process can use the equations of FIG. 8B-8D and is described in connection with the complex-zero equalizer 500 of FIG. 5 as an example. Block 900 begins a tuning process for a complex-pole equalizer. Block 901 determines initial settings of gm1, R1, Cs and C1. Note that adjustable resistors, transistors and capacitors may be used to allow these parameters to be tuned/adjusted. This can involve characterizing the VCSEL response separately, determining the rough frequency and quality factor of the complex-pole pair. The frequency ω_sub_n can be determined from the equation of FIG. 8C and the quality factor Q_sub_z can be determined from the equation of FIG. 8D, for example.

Block 902 includes determining the frequency and Q factor. A decision block 903 determines whether the frequency (freq.) is too low, e.g., below a desired or target frequency or range of frequencies, and the Q factor is too high, e.g., above a desired or target Q or range of Q. If the answer to the decision bock is yes, block 904 is reached, which involves coarse tuning by reducing R1 and/or fine tuning by changing C1 and/or Cs. With these actions, the frequency of the complex-zero can be increased and the Q factor can be reduced.

If the answer to the decision block 903 is no, then a decision block 905 determines whether the frequency is too high and the Q factor is too low. If the answer to the decision bock is yes, block 906 is reached, which involves coarse tuning by increasing R1 and/or fine tuning by changing C1 and/or Cs. With these actions, the frequency of the complex-zero can be decreased and the Q factor can be increased.

If the answer to the decision block 905 is no, then a decision block 907 determines whether the frequency is too low and the Q factor is too low. If the answer to the decision block is yes, block 908 is reached which involves coarse tuning by increasing gm1 and/or fine tuning by changing Cs, C1 and/or R1. With these actions, the frequency of the complex-zero can be increased and the Q factor can also be increased. Although, a limitation is imposed by the device's transit frequency. If the answer to the decision block 907 is no, then a decision block 909 determines whether the frequency is too high and the Q factor is too high. If the answer to the decision bock is yes, block 910 is reached, which involves coarse tuning by increasing C1 and/or Cs, and/or reducing gm1, and/or fine tuning by changing R1. With these actions, the frequency of the complex-zero can be decreased and the Q factor can also be decreased.

If the answer to the decision block 909 is no, then block 911 is reached. This block involves using the initial settings of gm1, R1, Cs and C1 since no adjustment is indicated by the previous blocks. In this case, the default setting of gm1, R1, CS and C1 results in satisfactory values of frequency and Q factor.

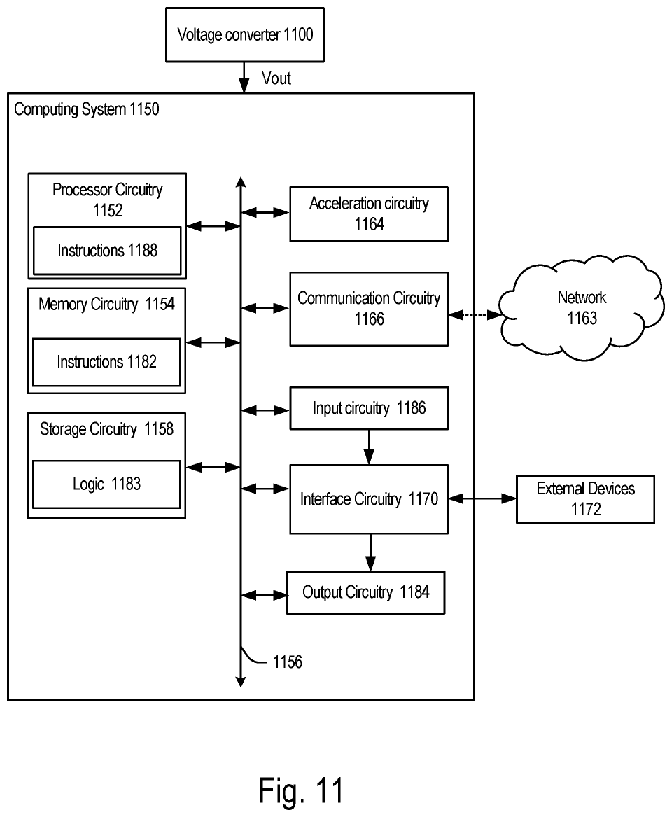

The tuning may be done, e.g., using either an on-chip control circuit or through an external control circuit. It can be done by the end user or at the time of testing also. The optimal performance point is achieved through eye monitoring and correspondingly tuning the various components. Eye monitoring is done by looking at the eye width as well as the eye height, and bit error rate contours. Once these fall below a certain threshold, re-tuning may be performed. An on-chip or external control circuit could be used to achieve the same. In an example implementation, the equalizer is tuned by the processor circuitry 1152 of FIG. 11 in a processor-implemented method. The processor circuitry may provide control signals to the equalizer such as to perform the tuning.

In one approach, a coarse tuning is first performed followed by a fine tuning. Although, it is also possible to perform a coarse tuning only, without a fine tuning, or a fine tuning only without a coarse tuning. The tuning can involve multiple iterations.

The tuning process can be the same for the CMOS implementation, e.g., of FIG. 7. The equations will be the same if gm1n=gm1p, gm0n=gm0p, R1n=Rlp, Csn=Csp and C1n=C1p. Otherwise, the theory of the tuning process remains the same.

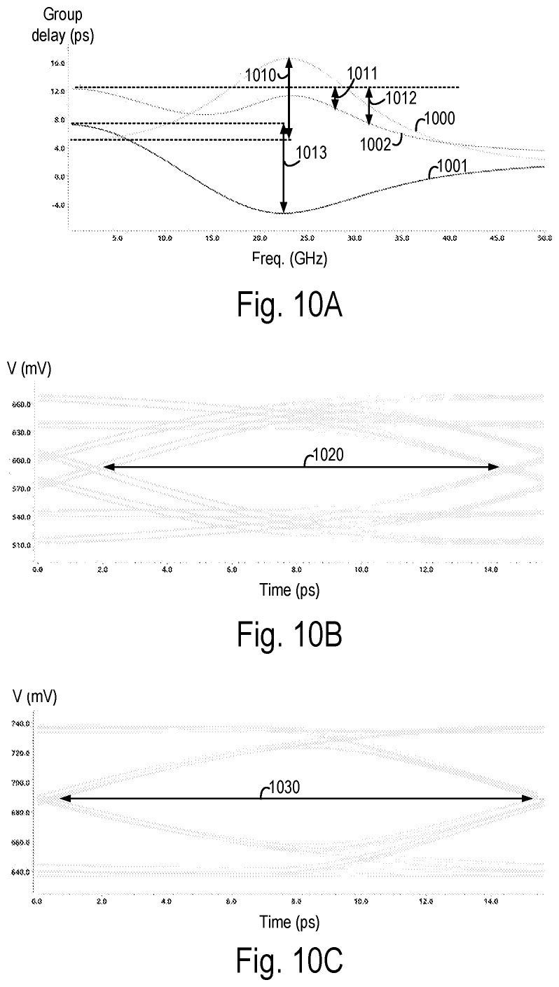

FIGS. 10A-10C illustrate the benefits of the complex-zero equalizer for a representative VCSEL response, based on a commercial VCSEL model, with ω_sub_n=25.2 GHz and =0.4. The underdamped nature of the response leads to a peaking of ˜11.5 ps at 23 GHz in the group delay response. R1, C1 and CS are set appropriately to achieve a dip of >12 ps at 22.5 GHz in the group delay response of the complex-zero equalizer. The cascaded response has <4 ps group delay variation at up to 28 GHz and ˜5 ps group delay variation at up to 32 GHz. The eye-diagram for a pseudorandom binary sequence (PRBS) at 64 Gb/s without the equalizer has an eye-width of 0.77 UI (FIG. 10B), and the equalizer improves this significantly to 0.93 UI (FIG. 10C), illustrating the efficacy of the active complex-zero equalizer.

FIG. 10A depicts example plots of group delay versus frequency for the optical transmitter of FIG. 2 with and without the complex-zero equalizer 500 of FIG. 5, in accordance with various embodiments. The plot 1000 depicts the VCSEL response. The plot 1001 depicts the complex-zero CTLE response. The plot 1002 depicts the cascade response, obtained by cascading the equalizer with the VCSEL driver.

The arrow 1010 depicts an approximately 11.5 ps (17-5.5) group delay peak of the VCSEL response at 23 GHz, and the arrow 1013 depicts an approximately 12.5 ps (8-(−4.5)) group delay dip of the complex-zero equalizer at 22.5 GHz. The dip in the response of the complex-zero equalizer thus largely counteracts the peak in the VCSEL response. Additionally, the cascade response is fairly flat as the arrow 1011 depicts a <4 ps variation in the cascade response at up to 28 GHz and the arrow 1012 depicts an approximately 5 ps variation in the cascade response at up to 32 GHz.

The figure thus depicts group delay frequency response, illustrating peaking in group delay due to VCSEL response, group delay compensation due to complex-zero equalizer, and group delay of the cascaded response.

FIG. 10B depicts an example eye diagram of the output of the optical transmitter of FIG. 2 without the complex-zero equalizer 500 of FIG. 5, in accordance with various embodiments. A degraded eye-width of 12.1 ps or 0.77 UI (arrow 1020) is observed due to the underdamped VCSEL response. The ratio of the eye height to the outer eye amplitude is 0.53, indicating a large intersymbol interference (ISI).

FIG. 10C depicts an example eye diagram of the output of the optical transmitter of FIG. 2 with the complex-zero equalizer 500 of FIG. 5, in accordance with various embodiments. The complex zero equalizer compensates for the group delay variation of the VCSEL and improves the eye-width to 14.5 ps or 0.93 UI (arrow 1030). The ratio of the eye height to the outer eye amplitude improves to 0.64, illustrating a reduction in the ISI.

The active complex-zero equalizer may be used for group delay compensation in any system with a complex-pole pair in its transfer function. A specific example is a multi-stage trans-impedance amplifier (TIA) used to realize higher trans-impedance gains than a single-stage TIA (see FIG. 3). However, the shunt feedback (path 304) around a multi-stage amplifier yields a frequency response with a high-Q complex-pole pair. This results in significant group delay peaking, which may be compensated using the active complex-zero equalizer.

FIG. 11 illustrates an example of components that may be present in a computing system 1150 for implementing the techniques (e.g., operations, processes, methods, and methodologies) described herein. A complex-zero equalizer 500, 600 or 700 may be present, e.g., in the input circuitry 1170 and/or output circuitry 1184. For example, the complex-zero equalizer could be in a transmitter 200 such as discussed in connection with FIG. 2, respectively, in the input circuitry 1170 and/or part of a receiver 300 such as discussed in connection with FIG. 3 in the output circuitry 1184. The complex-zero equalizer, transmitter and receiver may be controlled by the processor circuitry 1152.

A voltage converter 1100 may provide a voltage Vout to one or more of the components of the computing system 1150. The voltage converter may be controlled by control signals provided by the processor circuitry 1152.

The memory circuitry 1154 may store instructions and the processor circuitry 1152 may execute the instructions to perform the functions described herein.

The computing system 1150 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 1150, or as components otherwise incorporated within a chassis of a larger system. For one embodiment, at least one processor 1152 may be packaged together with computational logic 1182 and configured to practice aspects of various example embodiments described herein to form a System in Package (SiP) or a System on Chip (SoC).

The system 1150 includes processor circuitry in the form of one or more processors 1152. The processor circuitry 1152 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 1152 may include one or more hardware accelerators (e.g., same or similar to acceleration circuitry 1164), which may be microprocessors, programmable processing devices (e.g., FPGA, ASIC, etc.), or the like. The one or more accelerators may include, for example, computer vision and/or deep learning accelerators. In some implementations, the processor circuitry 1152 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein

The processor circuitry 1152 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low-voltage processor, an embedded processor, or any other known processing elements, or any suitable combination thereof. The processors (or cores) 1152 may be coupled with or may include memory/storage and may be configured to execute instructions stored in the memory/storage to enable various applications or operating systems to run on the platform 1150. The processors (or cores) 1152 is configured to operate application software to provide a specific service to a user of the platform 1150. In some embodiments, the processor(s) 1152 may be a special-purpose processor(s)/controller(s) configured (or configurable) to operate according to the various embodiments herein.

As examples, the processor(s) 1152 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centrig™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc.; or the like. In some implementations, the processor(s) 1152 may be a part of a system on a chip (SoC), System-in-Package (SiP), a multi-chip package (MCP), and/or the like, in which the processor(s) 1152 and other components are formed into a single integrated circuit, or a single package, such as the Edison™ or Galileo™ SoC boards from Intel® Corporation. Other examples of the processor(s) 1152 are mentioned elsewhere in the present disclosure.

The system 1150 may include or be coupled to acceleration circuitry 1164, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 1164 may comprise logic blocks or logic fabric and other interconnected resources that may be programmed (configured) to perform various functions, such as the procedures, methods, functions, etc. of the various embodiments discussed herein. In such implementations, the acceleration circuitry 1164 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 1152 and/or acceleration circuitry 1164 may include hardware elements specifically tailored for machine learning and/or artificial intelligence (AI) functionality. In these implementations, the processor circuitry 1152 and/or acceleration circuitry 1164 may be, or may include, an AI engine chip that can run many different kinds of AI instruction sets once loaded with the appropriate weightings and training code. Additionally or alternatively, the processor circuitry 1152 and/or acceleration circuitry 1164 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPs™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 1152 and/or acceleration circuitry 1164 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin 970 provided by Huawei®, and/or the like. In some hardware-based implementations, individual subsystems of system 1150 may be operated by the respective AI accelerating co-processor(s), AI GPUs, TPUs, or hardware accelerators (e.g., FPGAs, ASICs, DSPs, SoCs, etc.), etc., that are configured with appropriate logic blocks, bit stream(s), etc. to perform their respective functions.

The system 1150 also includes system memory 1154. Any number of memory devices may be used to provide for a given amount of system memory. As examples, the memory 1154 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 1154 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 1154 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 1158 provides persistent storage of information such as data, applications, operating systems and so forth. In an example, the storage 1158 may be implemented via a solid-state disk drive (SSDD) and/or high-speed electrically erasable memory (commonly referred to as “flash memory”). Other devices that may be used for the storage 1158 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 1154 and/or storage circuitry 1158 may also incorporate three-dimensional (3D) cross-point (XPOINT) memories from Intel® and Micron®.

The memory circuitry 1154 and/or storage circuitry 1158 is/are configured to store computational logic 1183 in the form of software, firmware, microcode, or hardware-level instructions to implement the techniques described herein. The computational logic 1183 may be employed to store working copies and/or permanent copies of programming instructions, or data to create the programming instructions, for the operation of various components of system 1150 (e.g., drivers, libraries, application programming interfaces (APIs), etc.), an operating system of system 1150, one or more applications, and/or for carrying out the embodiments discussed herein. The computational logic 1183 may be stored or loaded into memory circuitry 1154 as instructions 1182, or data to create the instructions 1182, which are then accessed for execution by the processor circuitry 1152 to carry out the functions described herein. The processor circuitry 1152 and/or the acceleration circuitry 1164 accesses the memory circuitry 1154 and/or the storage circuitry 1158 over the interconnect (IX) 1156. The instructions 1182 direct the processor circuitry 1152 to perform a specific sequence or flow of actions, for example, as described with respect to flowchart(s) and block diagram(s) of operations and functionality depicted previously. The various elements may be implemented by assembler instructions supported by processor circuitry 1152 or high-level languages that may be compiled into instructions 1188, or data to create the instructions 1188, to be executed by the processor circuitry 1152. The permanent copy of the programming instructions may be placed into persistent storage devices of storage circuitry 1158 in the factory or in the field through, for example, a distribution medium (not shown), through a communication interface (e.g., from a distribution server (not shown)), over-the-air (OTA), or any combination thereof.

The IX 1156 couples the processor 1152 to communication circuitry 1166 for communications with other devices, such as a remote server (not shown) and the like. The communication circuitry 1166 is a hardware element, or collection of hardware elements, used to communicate over one or more networks 1163 and/or with other devices. In one example, communication circuitry 1166 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 1166 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 1156 also couples the processor 1152 to interface circuitry 1170 that is used to connect system 1150 with one or more external devices 1172. The external devices 1172 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 1150, which are referred to as input circuitry 1186 and output circuitry 1184. The input circuitry 1186 and output circuitry 1184 include one or more user interfaces designed to enable user interaction with the platform 1150 and/or peripheral component interfaces designed to enable peripheral component interaction with the platform 1150. Input circuitry 1186 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 1184 may be included to show information or otherwise convey information, such as sensor readings, actuator position(s), or other like information. Data and/or graphics may be displayed on one or more user interface components of the output circuitry 1184. Output circuitry 1184 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 1150. The output circuitry 1184 may also include speakers and/or other audio emitting devices, printer(s), and/or the like. Additionally or alternatively, sensor(s) may be used as the input circuitry 1184 (e.g., an image capture device, motion capture device, or the like) and one or more actuators may be used as the output device circuitry 1184 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 1150 may communicate over the IX 1156. The IX 1156 may include any number of technologies, including ISA, extended ISA, I2C, SPI, point-to-point interfaces, power management bus (PMBus), PCI, PCIe, PCIx, Intel® UPI, Intel@Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 1156 may be a proprietary bus, for example, used in a SoC based system.

The number, capability, and/or capacity of the elements of system 1150 may vary, depending on whether computing system 1150 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 1150 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible, non-transitory machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

Some non-limiting examples of various embodiments are presented below.

Example 1 includes an equalizer, comprising: an input path; a first transistor having a control gate coupled to the input path, a drain coupled to an output path, and a source; and first, second and third paths coupled between the source and ground; wherein: the first path comprises, in series, a resistor, a node and a first capacitor; the second path comprises a second transistor having a control gate coupled to the node; and the third path comprises a second capacitor.

Example 2 includes the equalizer of Example 1, further comprising a bypass path to bypass the resistor, and a switch to couple the source of the first transistor to the resistor or the bypass path.

Example 3 includes the equalizer of Example 2, wherein: when the source of the first transistor is coupled to the bypass path, the equalizer is a real-zero equalizer; and when the source of the first transistor is coupled to the resistor, the equalizer is a complex-zero equalizer.

Example 4 includes the equalizer of any one of Examples 1-3, wherein the equalizer is a complex-zero equalizer to compensate for a peak in a group delay response of a broadband amplifier, and the peak has a complex-pole pair.

Example 5 includes the equalizer of Example 4, wherein the broadband amplifier comprises a single-stage or multi-stage trans-impedance amplifier.

Example 6 includes the equalizer of any one of Examples 1-5, wherein: the equalizer is part of a transmitter for a Vertical Cavity Surface Emitting Laser (VCSEL); an optical response of the VCSEL has a complex-pole pair, resulting in a peak in a group delay response; and the equalizer is a complex-zero equalizer to counteract the peak in the group delay response.

Example 7 includes the equalizer of any one of Examples 1-6, wherein the resistor and the first and second capacitors are adjustable.

Example 8 includes the equalizer of any one of Examples 1-7, wherein a transconductance of the second transistor is adjustable.

Example 9 includes the equalizer of any one of Examples 1-8, further comprising at least one of input circuitry, output circuitry, a System on Chip, a System in Package or a computing device in which the input path, output path, first transistor and first, second and third paths are provided.

Example 10 includes the equalizer of any one of Examples 1-9, wherein the first and second transistors comprise n-type metal-oxide-semiconductor field-effect transistors.

Example 11 includes an equalizer, comprising: an input path to receive an input voltage; a first transistor arranged in series with a second transistor, wherein the first transistor comprises a control gate coupled to the input path, a source coupled to an output path, and a drain, the second transistor comprises a control gate coupled to the input path, a drain coupled to the output path, and a source, and the output path is to provide an output voltage; a first circuit coupled to the drain of the first transistor; and a second circuit coupled to the source of the second transistor.

Example 12 includes the equalizer of Example 11, wherein: the first circuit comprises first, second and third paths coupled between a power supply node and the drain of the first transistor; and in the first circuit: the first path comprises, in series, a capacitor, a node and a resistor, the second path comprises a third transistor having a control gate coupled to the node, and the third path comprises a capacitor.

Example 13 includes the equalizer of Example 12, wherein: the second circuit comprises first, second and third paths coupled between ground and the source of the second transistor; and in the second circuit: the first path comprises, in series, a resistor, a node and a capacitor, the second path comprises a fourth transistor having a control gate coupled to the node, and the third path comprises a capacitor.

Example 14 includes the equalizer of any one of Examples 11-13, wherein: the equalizer follows an output of a trans-impedance amplifier; the equalizer is a complex-zero equalizer; the equalizer is to counteract a peak in a group delay response of the trans-impedance amplifier; and the peak has a complex-pole pair.

Example 15 includes the equalizer of any one of Examples 11-14, wherein the equalizer is implemented in a Complementary Metal-Oxide Semiconductor.

Example 16 includes the equalizer of any one of Examples 11-14, wherein a source of the first transistor is coupled to a drain of the second transistor and the first and second transistors comprise n-type metal-oxide-semiconductor field-effect transistors (nMOSFETs).

Example 17 includes a non-transitory, computer-readable medium comprising instructions that, when executed by a processor, cause the processor to: determine a frequency and quality (Q) factor of a complex-zero pole pair of an equalizer circuit with initial settings, wherein the equalizer circuit comprises an input path (407), a first transistor (404) having a control gate coupled to the input path (407), a drain coupled to an output path (403), a source (406), and first, second and third paths (510, 511, 512) coupled between the source and ground, the first path comprises, in series, a resistor, a node (513) and a first capacitor (514), the second path comprises a second transistor (509) having a control gate coupled to the node, and the third path comprises a second capacitor (413), and the initial settings comprise a transconductance (gm1) of the second transistor, a resistance (R1) of the resistor, a first capacitance (Cs) of the first capacitor and a second capacitance (C1) of the second capacitor; determine whether the frequency is too high, above a desired frequency range, or too low, below the desired frequency range; determine whether the Q factor is too high, above a desired Q factor range, or too low, below the desired Q factor range; and adjust one or more of the transconductance, the resistance, the first capacitance or the second capacitance, based on whether the frequency is too high or too low and whether the Q factor is too high or too low.

Example 18 includes the non-transitory, computer-readable medium of Example 17, wherein the adjusting comprises: reducing the resistance when the frequency is too low and the Q factor is too high; and increasing the resistance when the frequency is too high and the Q factor is too low.

Example 19 includes the non-transitory, computer-readable medium of Example 17 or 18, wherein the adjusting comprises increasing the transconductance when the frequency is too low and the Q factor is too low.

Example 20 includes the non-transitory, computer-readable medium of any one of Examples 17-19, wherein the adjusting comprises increasing the first capacitance and/or the second capacitance and/or reducing the transconductance when the frequency is too high and the Q factor is too high.

Example 21 includes a non-transitory machine-readable storage including machine-readable instructions that, when executed, cause a processor or other circuit or computing device to implement the method of any one of Examples 17-20.

Example 22 includes a computer program comprising instructions which, when the program is executed by a computer, cause the computer to carry out the method of any one of Examples 17-20.

Example 23 includes a method, comprising: with a complex-zero equalizer, compensating for a peak in a group delay response of a broadband amplifier, wherein the peak has a complex-pole pair.

Example 24 includes the method of Example 23, wherein the broadband amplifier comprises a single-stage or multi-stage trans-impedance amplifier.

Example 25 includes a non-transitory machine-readable storage including machine-readable instructions that, when executed, cause a processor or other circuit or computing device to implement the method of Example 23 or 24. Example 26 includes a computer program comprising instructions which, when the program is executed by a computer, cause the computer to carry out the method of Example 23 or 24.

Example 27 includes a method, comprising: with a complex-zero equalizer, counteracting a peak in a group delay response of a Vertical Cavity Surface Emitting Laser (VCSEL), wherein the equalizer is part of a transmitter for the VCSEL; and an optical response of the VCSEL has a complex-pole pair, resulting in the peak in the group delay response.

Example 28 includes a non-transitory machine-readable storage including machine-readable instructions that, when executed, cause a processor or other circuit or computing device to implement the method of Example 27.

Example 29 includes a computer program comprising instructions which, when the program is executed by a computer, cause the computer to carry out the method of Example 27. In the present detailed description, reference is made to the accompanying drawings that form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An equalizer, comprising:
an input path;
a first transistor having a control gate coupled to the input path, a drain coupled to an output path, and a source; and
first, second and third paths coupled between the source and ground; wherein:
the first path comprises, in series, a resistor, a node and a first capacitor;
the second path comprises a second transistor having a control gate coupled to the node; and
the third path comprises a second capacitor.

2. The equalizer of claim 1, further comprising a bypass path to bypass the resistor, and a switch to couple the source of the first transistor to the resistor or the bypass path.

3. The equalizer of claim 2, wherein:
when the source of the first transistor is coupled to the bypass path, the equalizer is a real-zero equalizer; and
when the source of the first transistor is coupled to the resistor, the equalizer is a complex-zero equalizer.

4. The equalizer of claim 1, wherein the equalizer is a complex-zero equalizer to compensate for a peak in a group delay response of a broadband amplifier, and the peak has a complex-pole pair.

5. The equalizer of claim 4, wherein the broadband amplifier comprises a single-stage or multi-stage trans-impedance amplifier.

6. The equalizer of claim 1, wherein:
the equalizer is part of a transmitter for a Vertical Cavity Surface Emitting Laser (VCSEL);
an optical response of the VCSEL has a complex-pole pair, resulting in a peak in a group delay response; and
the equalizer is a complex-zero equalizer to counteract the peak in the group delay response.

7. The equalizer of claim 1, wherein the resistor and the first and second capacitors are adjustable.

8. The equalizer of claim 1, wherein a transconductance of the second transistor is adjustable.

9. The equalizer of claim 1, further comprising at least one of input circuitry, output circuitry, a System on Chip, a System in Package or a computing device in which the input path, output path, first transistor and first, second and third paths are provided.

10. The equalizer of claim 1, wherein the first and second transistors comprise n-type metal-oxide-semiconductor field-effect transistors.

11. An equalizer, comprising:
an input path to receive an input voltage;
a first transistor arranged in series with a second transistor, wherein the first transistor comprises a control gate coupled to the input path, a source coupled to an output path, and a drain, the second transistor comprises a control gate coupled to the input path, a drain coupled to the output path, and a source, and the output path is to provide an output voltage;
a first circuit coupled to the drain of the first transistor; and
a second circuit coupled to the source of the second transistor.

12. The equalizer of claim 11, wherein:
the first circuit comprises first, second and third paths coupled between a power supply node and the drain of the first transistor; and
in the first circuit: the first path comprises, in series, a capacitor, a node and a resistor, the second path comprises a third transistor having a control gate coupled to the node, and the third path comprises a capacitor.

13. The equalizer of claim 12, wherein:
the second circuit comprises first, second and third paths coupled between ground and the source of the second transistor; and
in the second circuit, the first path comprises, in series, a resistor, a node and a capacitor, the second path comprises a fourth transistor having a control gate coupled to the node, and the third path comprises a capacitor.

14. The equalizer of claim 11, wherein:
the equalizer follows an output of a trans-impedance amplifier;
the equalizer is a complex-zero equalizer;
the equalizer is to counteract a peak in a group delay response of the trans-impedance amplifier; and
the peak has a complex-pole pair.

15. The equalizer of claim 11, wherein the equalizer is implemented in a Complementary Metal-Oxide Semiconductor.

16. The equalizer of claim 11, wherein a source of the first transistor is coupled to a drain of the second transistor and the first and second transistors comprise n-type metal-oxide-semiconductor field-effect transistors (nMOSFETs).

17. A non-transitory, computer-readable medium comprising instructions that, when executed by a processor, cause the processor to:
determine a frequency and quality (Q) factor of a complex-zero pole pair of an equalizer circuit with initial settings, wherein the equalizer circuit comprises an input path, a first transistor having a control gate coupled to the input path, a drain coupled to an output path, a source, and first, second and third paths coupled between the source and ground, the first path comprises, in series, a resistor, a node and a first capacitor, the second path comprises a second transistor having a control gate coupled to the node, and the third path comprises a second capacitor, and the initial settings comprise a transconductance of the second transistor, a resistance of the resistor, a first capacitance of the first capacitor and a second capacitance of the second capacitor;
determine whether the frequency is too high, above a desired frequency range, or too low, below the desired frequency range;
determine whether the Q factor is too high, above a desired Q factor range, or too low, below the desired Q factor range; and
adjust one or more of the transconductance, the resistance, the first capacitance or the second capacitance, based on whether the frequency is too high or too low and whether the Q factor is too high or too low.

18. The non-transitory, computer-readable medium of claim 17, wherein the adjusting comprises:
reducing the resistance when the frequency is too low and the Q factor is too high; and
increasing the resistance when the frequency is too high and the Q factor is too low.

19. The non-transitory, computer-readable medium of claim 17, wherein the adjusting comprises increasing the transconductance when the frequency is too low and the Q factor is too low.

20. The non-transitory, computer-readable medium of claim 17, wherein the adjusting comprises increasing the first capacitance and/or the second capacitance and/or reducing the transconductance when the frequency is too high and the Q factor is too high.
